(19) United States
(12) Patent Application Publication
(10) Pub. No.: US 2007/0029131 A1
(43) Pub. Date: Feb. 8, 2007

(54) SPEAKER MODULE WITH EXPANDABLE ENCLOSURE

(75) Inventors: Cheng-Chia Pan, TU CHENG (TW); Shih-Chia Chiu, TU CHENG (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: Foxconn Technology Co., Ltd., TU CHENG (TW)

(21) Appl. No.: 11/308,773

(22) Filed: May 2, 2006

(30) Foreign Application Priority Data
Aug. 5, 2005 (CN) 200510036436.7

(51) Int. Cl. A47B 81/06; H05K 5/00

(52) U.S. Cl. 181/148; 181/199

(57) ABSTRACT

A speaker module with expandable enclosure includes a speaker (20) and an enclosure (10) receiving the speaker therein. The enclosure includes a plurality of boxes (60, 70, 80) communicating with each other. Each box is extendable relative to an adjacent box to thereby adjust the volume of the enclosure. Furthermore, when the speaker does not work the boxes can be retracted to thereby save a space occupied by the speaker module.

### FIELD OF THE INVENTION

The present invention relates generally to audio system of electronic devices, and more particularly to a speaker module with good sound capability.

### Description of Related Art

Portable electronic devices, such as notebook, CD player, MP3 and the like, have decreased both in size and weight over the past few years and are becoming ever more popular with travelers. This demand for smaller size with ever-increasing capability has required a tremendous effort to continually shrink many of the components contained within the device.

For a notebook computer, examples of component shrinkage are the hard disk storage, the circuitry, tracking devices, compact disc drives, speakers, and even the connectors. The reduction in the size of many of these components has not been a serious problem, since technological advancements have allowed both improved capabilities along with smaller size. However, portable electronic devices being designed today require the ability to operate with multi-media features and provide the user with the same enjoyable experience as that experienced from conventional high quality desktop systems. Thus, the sound emanating from a portable electronic device should provide as full a harmonic content as the original sound. The production of low frequency sound requires the movement of a large mass of air to be heard. As the speaker is reduced in size, the maximum power the speaker can handle is also reduced, resulting in both a reduction in loudness as well as a poorer overall quality of sound. However, increasing the device size to accommodate larger loudspeaker and larger speaker-box sizes is very undesirable since it would strongly detract from the very characteristics that have helped to make these devices popular, namely size and weight. Thus the size is at odds with high capability sound of the speaker.

Therefore, there is a need for a speaker module with expandable enclosure which has smaller size and good sound capability.

### SUMMARY OF THE INVENTION

According to a preferred embodiment of the present invention, a speaker module with an expandable enclosure comprises a loudspeaker and an enclosure receiving the loudspeaker therein. The loudspeaker is mounted on a mounting wall of the enclosure. The enclosure comprises a plurality of boxes communicating with each other. Each box is extendable and retractable relative to an adjacent box to thereby adjust the volume of the enclosure. The present invention can thus adjust the amount of air driven by the loudspeaker, thereby to obtain the optimal sound quality. Furthermore, when the speaker does not work the boxes can be extracted to thereby save the space occupied by the speaker module.

Other advantages and novel features of the present invention will be drawn from the following detailed description of a preferred embodiment of the present invention with attached drawings, in which:

### BRIEF DESCRIPTION OF THE DRAWINGS

FIG. 1 is an isometric view of a speaker module with an expandable enclosure in accordance with a preferred embodiment of the present invention, wherein the speaker module is at an unexpanded configuration having a minimum volume;

FIG. 2 is a side view of the speaker module of FIG. 1;

FIG. 3 shows the speaker module of FIG. 1 in its first expanded configuration having a middle volume;

FIG. 4 shows a side view of the speaker module of FIG. 3;

FIG. 5 shows the speaker module of FIG. 1 in its second expanded configuration having a maximum volume;

FIG. 6 is a side view of the speaker module of FIG. 5;

FIG. 7 shows a speaker module in its unexpanded configuration, according to a second embodiment of the present invention;

FIG. 8 is a top side view of the speaker module of FIG. 7;

FIG. 9 shows the speaker module of FIG. 7 in its first expanded configuration;

FIG. 10 is a top side view of the speaker module of FIG. 9;

FIG. 11 shows the speaker module of FIG. 7 in its second expanded configuration; and

FIG. 12 is a top side view of the speaker module of FIG. 11.

### DETAILED DESCRIPTION OF THE INVENTION

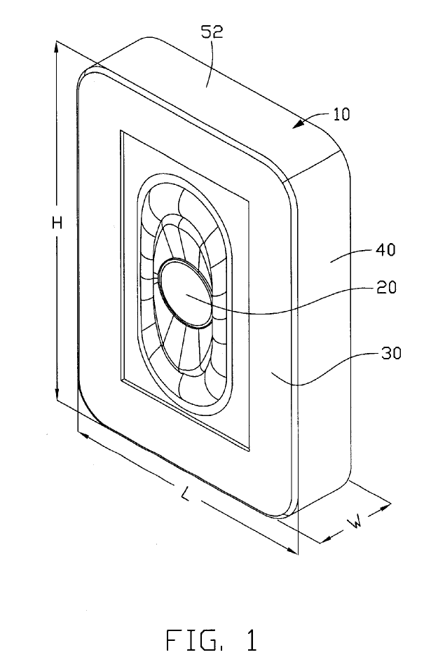

Referring to FIGS. 1-6, a speaker module with an expandable enclosure according to a preferred embodiment of the present invention includes an enclosure 10 and a loudspeaker 20 mounted on the enclosure 10.

The enclosure 10 includes a front wall 30, and a back wall (not labeled) parallel to the front wall 30. A top side wall 50, a bottom side wall (not labeled), a left side wall (not labeled), and a right side wall 40 interconnecting four sides (i.e., top, bottom, left and right sides) of the front wall 30 and the back wall, respectively. Each wall of the enclosure 10 is rectangle shaped. The six walls cooperatively form a cuboid shaped space for receiving the loudspeaker 20 therein. Also the walls can be formed in other shape, and thus enable the enclosure 10 to have other shape. The loudspeaker 20 is mounted on the front wall 30 and received in the space of the enclosure 10. The front wall 30 has a length of L, and a height of H.

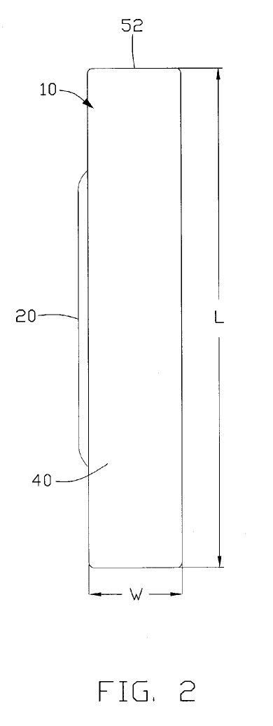

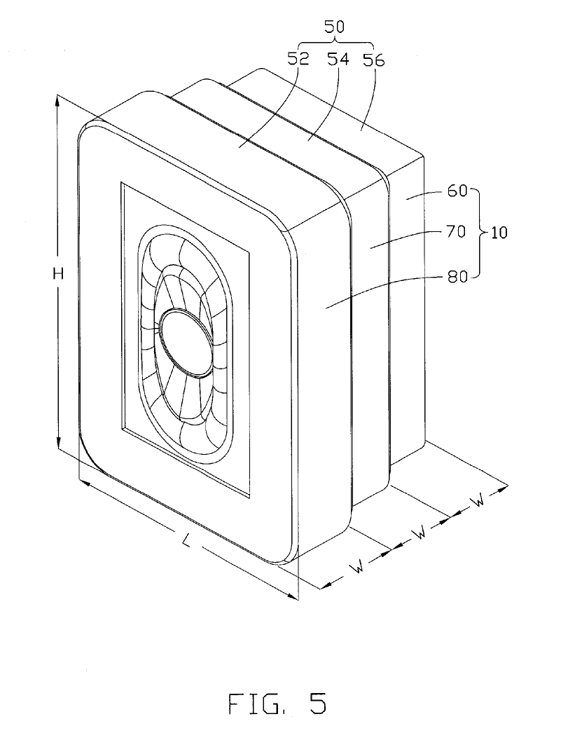

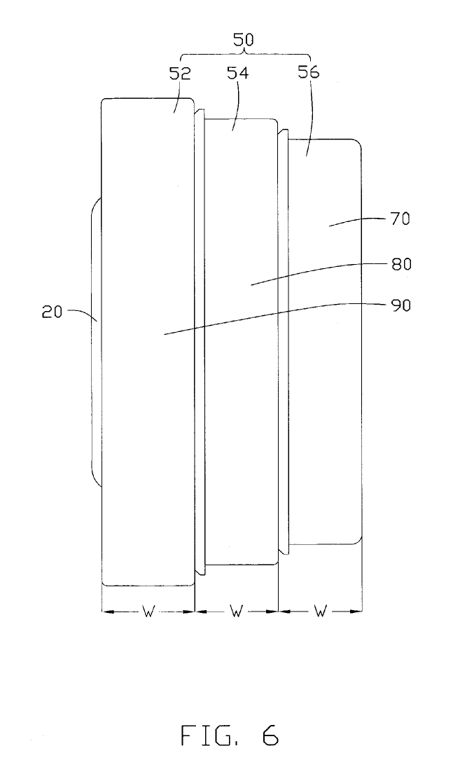

The top side wall 50 includes three sections, namely in sequence, an outer section 52, a middle section 54 and an inner section 56 (as shown in FIGS. 5-6). Each of the three sections 52, 54, 56 is moveable relative to an adjacent section of the top side wall 50. The three sections 52, 54, 56 can be stacked together in such a manner that the outer section 52 is the outermost periphery of the enclosure 10 (as shown in FIGS. 1-2). The three sections 52, 54, 56 each have a width of W. Therefore the top side wall 50 has a width variable from W to triple W. The bottom side, left side wall and right side wall 40 each includes an outer section, a middle section and an inner section corresponding to the three sections 52, 54, 56 of the top side wall 50. The inner sections of the four side walls cooperatively define a hollow inner box 60. The volume of the inner box 60 is about L*W*H. The middle sections of the four side walls cooperatively define a hollow middle box 70, whilst the outer sections of the four side walls cooperatively define a hollow outer box 80. The outer box 80 movably engages with the middle box 70. The middle box 70 movably engages with the inner box 60. Thus the three boxes 80, 70, 60 telescopically connect together. The middle and outer boxes 70, 80 each has approximately the same volume as the inner box 60. Thus, each of the three boxes 80, 70, 60 has a volume of L*W*H. The volume of the enclosure 10 is variable from L*W*H to 3*L*W*H.

FIGS. 1-2 show the enclosure 10 in its unexpanded configuration. In this status, the three sections 52, 54, 56 of the top side wall 50 (also the three sections of the bottom side wall, the left wall, and the right wall 40) overlap with each other. In other words, the inner and middle boxes 60, 70 are received in the outer box 80. Together the front and back walls, and side walls of the outer box 80 defines the space of the enclosure 10. The enclosure 10 has a minimum width of W as that of the outer section 52 of the top side wall 50. The enclosure 10 has a minimum volume of L*W*H as the volume of the outer box 80.

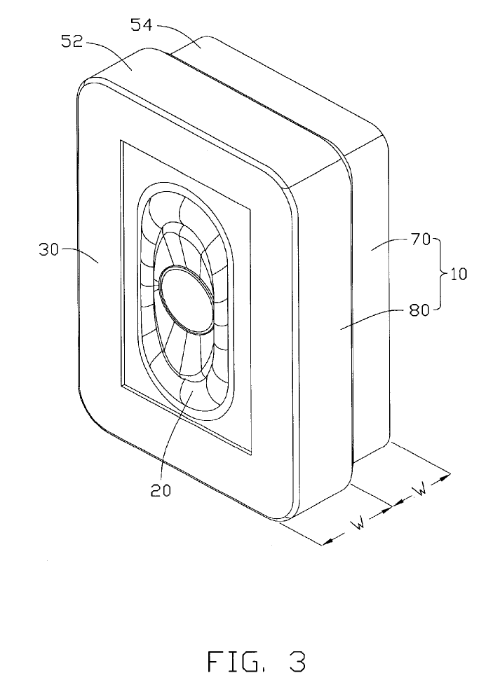

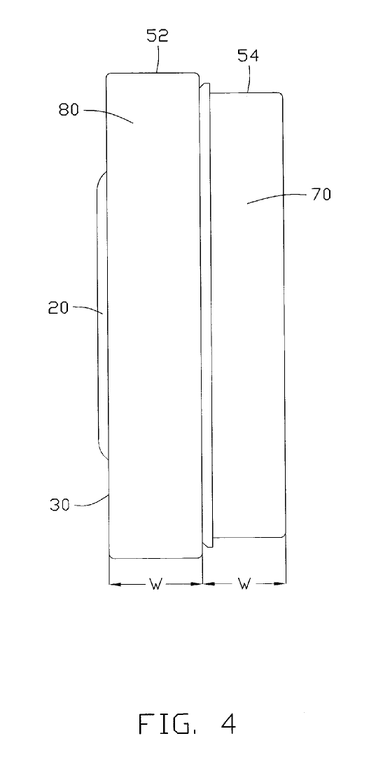

FIGS. 3-4 show the enclosure 10 in its first expanded configuration. Only the side walls of the inner sections overlap with the side walls of the middle sections. The middle box 70 moves outwardly from the outer box 80 along a direction perpendicular to the front wall 30 of the enclosure 10 with the inner box 60 received in the middle box 70. The width of the enclosure 10 is 2*W, equal to a summation of the width of the outer section 52 and middle section 54. Therefore the enclosure 10 has a volume of 2*L*W*H, equal to a summation of the volume of the outer box 80 and middle box 70. The enclosure 10 in its first expanded configuration has a middle volume which is twice of that of the enclosure 10 in its unexpanded configuration. Thus amount of air in the enclosure 10 that the loudspeaker 20 can drive to generate sound in the first expanded configuration is twice as much as that when the enclosure 10 is in its unexpanded configuration, resulting in both an enhancement in loudness as well as a better overall quality of sound.

As shown in FIGS. 5-6, the enclosure 10 is in its second expanded configuration. The middle box 70 moves outwardly from the outer box 80 along the direction perpendicular to front wall 30 of the enclosure 10. The inner box 60 moves outwardly from the middle box 70. The enclosure 10 has a width equal to a summation of the width the three sections 52, 54, 56 of the top side wall 50. Thus the enclosure 10 has a width of 3*W, and has a volume of 3*L*W*H. Therefore the amount of air that the loudspeaker 20 can drive to generate the sound in the second expanded configuration is triple as much as that when the enclosure 10 is in its unexpanded configuration. Thus, the speaker module can further improve loudness as well as overall quality of sound.

Alternatively, two adjacent boxes can be overlapped partly. For example, half of the inner and middle boxes 60, 70 are overlapped when the speaker module is fully expanded. In this manner, the width of the enclosure 10 is about 2.5*W, and the volume is about 2.5*L*W*H. Therefore, the volume of the enclosure 10 can be adjusted from L*W*H to 2.5*L*W*H. In operation of the speaker module, the volume of the enclosure 10 is adjusted by the movement of the boxes 60, 70, 80 of the enclosure 10. Thus improving the amount of air driven by the loudspeaker 20. Thus, the sound emanating from the speaker module can have better quality and is sounded more like the original sound. Portable electronic devices with the speaker module can provide the user with the same enjoyable experience as that experienced from conventional high quality desktop systems. Whereas, the inner and middle boxes 60, 70 can be received in the outer box 80 to thereby save the space the speaker module occupied when the speaker module does not work. Finally the speaker module with expandable configuration provides a small carrying size so as to meet the miniaturization requirement of electronic products, and also provides good sound capability. A user can adjust the volume of the speaker module to obtain a personal favorite sound quality. The present invention give consider to the sound quality and miniaturization trend.

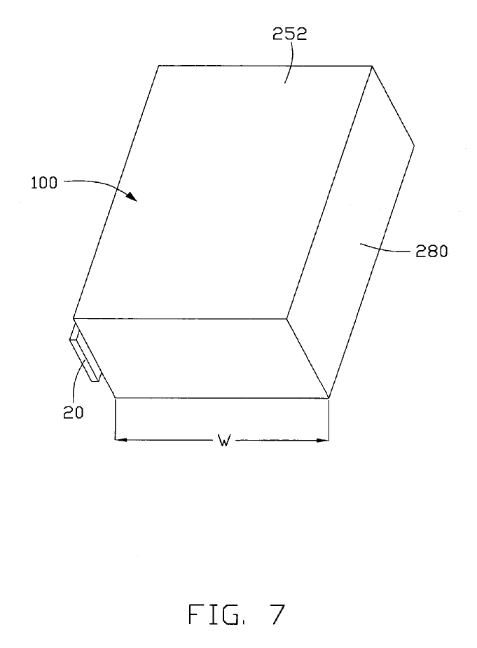

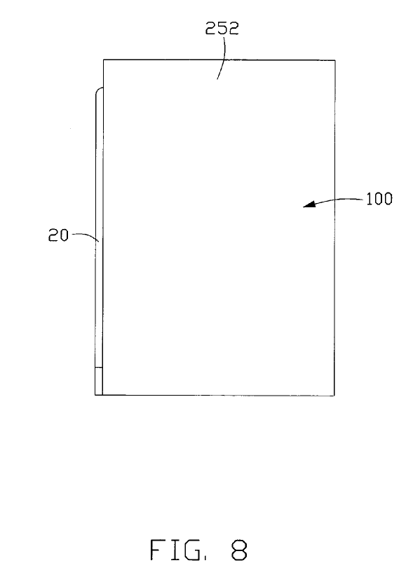

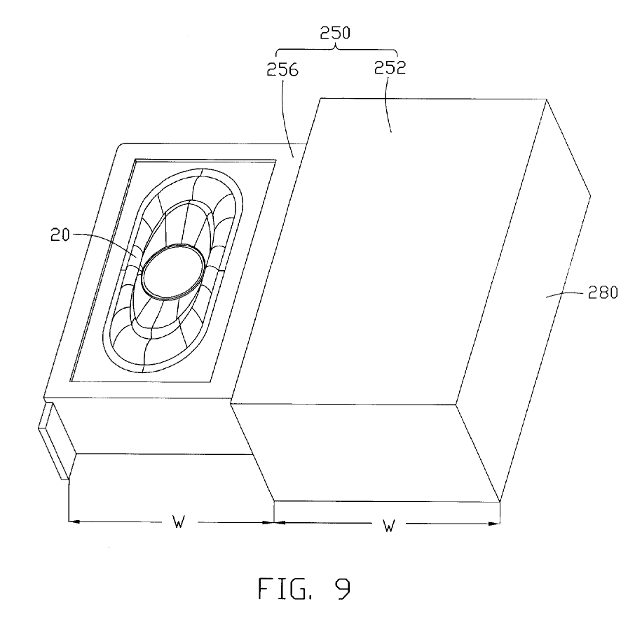

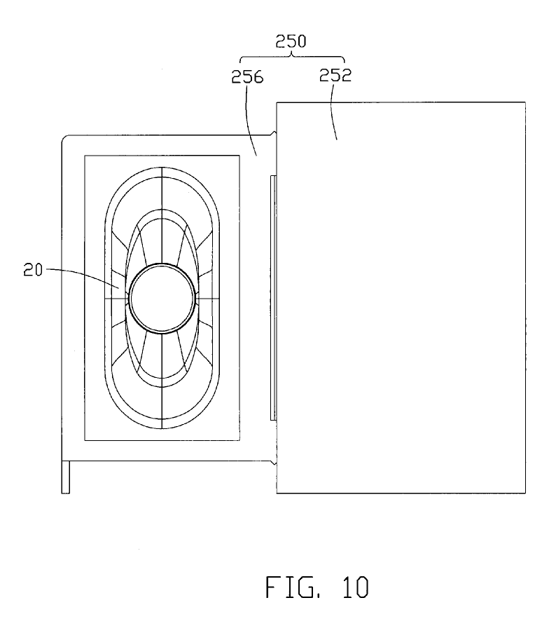

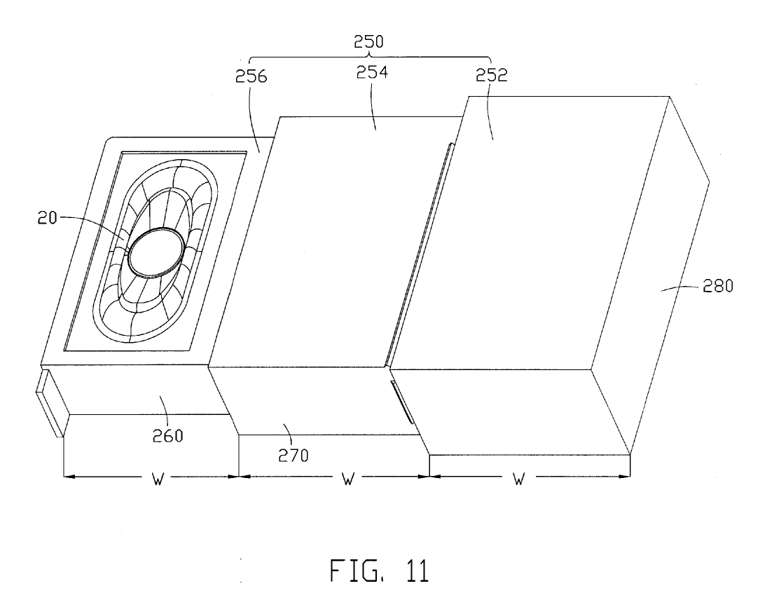

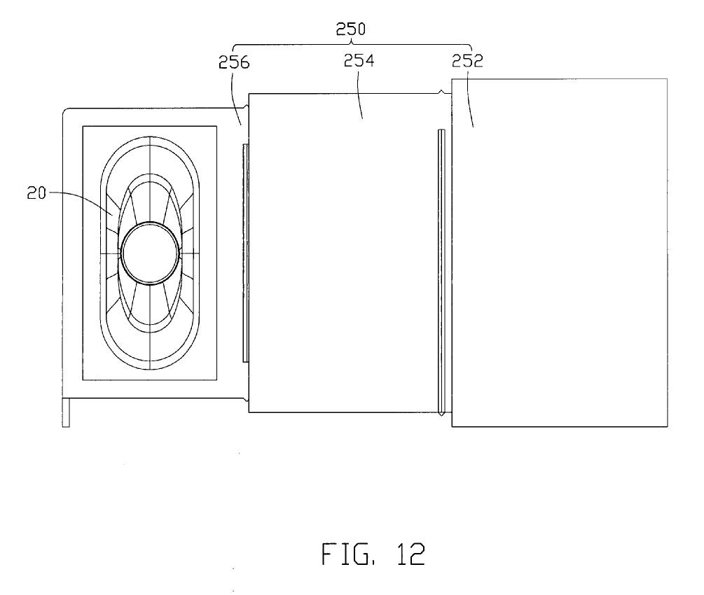

FIGS. 7-12 show another embodiment of the speaker module of the present invention. Except for the location of the loudspeaker 20, other parts of the speaker module in accordance with this second embodiment have substantially the same configurations with the speaker module of the previous first preferred embodiment. In this embodiment, the top side wall 250 of the enclosure 100 includes an outer section 252, a middle section 254 and an inner section 256 (which is also the bottom side wall, the left wall, and the right wall). Each of the sections is moveable relative to an adjacent section. The inner section 256 of the top side wall 250 defines a mounting wall for mounting the loudspeaker 20 thereon. According to the three sections of the top side walls, the enclosure 100 forms an outer box 280, a middle box 270, and an inner box 260. Each of the boxes 260, 270, 280 is moveable relative to an adjacent box. The three boxes 260, 270, 280 move along a direction parallel to the top side wall 250 to adjust the volume of the enclosure 100. The loudspeaker 20 is mounted on the top side wall 250 of the inner box 260. As shown in FIGS. 7-8, the enclosure 100 is in its unexpanded configuration. FIGS. 9-10 show the enclosure 100 in its first expanded configuration. Only the inner box 260 extends outwardly from the outer box 280. The enclosure 100 in its first expanded configuration has a width of 2*W twice of that of the unexpanded configuration, and thus has a volume twice of that of the unexpanded configuration. FIGS. 9-10 show the enclosure 100 in its second expanded configuration. The inner box 260 extends outwardly from the middle box 270, and the middle box 270 extends outwardly from the outer box 280. The enclosure 100 in its second expanded configuration has a maximum width of 3*W, triple of that of the unexpanded configuration, and thus has a volume triple of that of the unexpanded configuration.

The enclosure 10 (100) of the two embodiments each includes three boxes 60 (260), 70 (270), 80 (280). Alternatively, the number of boxes of the enclosure can be more or less than three. For example, the enclosure consists of five boxes. The maximum volume of the enclosure is five times of that of the minimum volume of the enclosure. The range of amount of air that the loudspeaker can drive is further broadened.

It is understood that the invention may be embodied in other forms without departing from the spirit thereof. Thus, the present example and embodiment is to be considered in all respects as illustrative and not restrictive, and the invention is not to be limited to the details given herein.

What is claimed is:

1. A speaker module with expandable enclosure comprising:
a loudspeaker; and
an enclosure comprising a mounting wall mounting the loudspeaker thereon, the enclosure having at least three boxes communicating with each other, each of the at least three boxes being moveable relative to an adjacent box so that a volume of the enclosure is adjustable, the mounting wall being on one of the at least three boxes.

2. The speaker module as claimed in claim 1, wherein the each box is moveable along a direction parallel to the mounting wall.

3. The speaker module as claimed in claim 1, wherein the each box is moveable along a direction perpendicular to the mounting wall.

4. The speaker module as claimed in claim 1, wherein the enclosure comprises an outer box and at least an inner box moveably received in the outer box, the outer box comprises the mounting wall mounting the loudspeaker thereon.

5. The speaker module as claimed in claim 1, wherein the enclosure comprises an inner box and at least an outer box moveably receiving the inner box therein, the inner box comprises the mounting wall mounting the loudspeaker thereon.

6. The speaker module as claimed in claim 1, wherein the enclosure comprises an inner box, an outer box and a middle box interconnecting the outer and inner box.

7. The speaker module as claimed in claim 1, wherein each box of the enclosure is cuboid shaped.

8. A speaker module with expandable enclosure comprising:
a loudspeaker; and
an enclosure comprising several walls defining a space receiving the loudspeaker therein;
wherein at least one of the several walls has a size variable to adjust the volume of the enclosure from an minimum volume to an maximum volume, the maximum volume of the enclosure is at least triple of the minimum volume.

9. The speaker module as claimed in claim 8, wherein the loudspeaker is mounted on one of the several walls.

10. The speaker module as claimed in claim 8, wherein the loudspeaker is mounted on a wall different from the at least one of the several walls.

11. The speaker module as claimed in claim 9, wherein the at least one of the several walls includes several sections, each section is moveable relative to an adjacent section to adjust the size of the at least one of the several walls.

12. A speaker module comprising:
a first box having a loudspeaker mounted thereon;
a second box telescopically mounted to the first box; and
a third box telescopically mounted on the second box;
wherein when the loudspeaker is activated, an air surrounded by the first, second and third boxes is driven by the loudspeaker.

13. The speaker module as claimed in claim 12, wherein the first box is larger than the second box and the second box is larger than the third box.

14. The speaker module as claimed in claim 13, wherein the loudspeaker is mounted on a front wall of the first box, and the second box is telescopically rearwards mounted to the first box, and the third box is telescopically rearwards mounted to the second box.
